(19) United States
(12) Patent Application Publication
(10) Pub. No.: US 2012/0017833 A1
(43) Pub. Date: Jan. 26, 2012

(54) CONVEYOR DEVICE AND SUBSTRATE TREATMENT INSTALLATION

(75) Inventors: Hubertus Von Der Waydbrink, Dresden (DE); Michael Hentschel, Dresden (DE); Marco Kenne, Dresden (DE); Steffen Lessmann, Dresden (DE); Thomas Peunsch, Dresden (DE); Reinhard Jaeger, Coswig (DE)

(73) Assignee: VON ARDENNE ANLAGENTECHNIK GMBH, Dresden (DE)

(21) Appl. No.: 13/130,879

(22) PCT Filed: Jan. 14, 2011
(86) PCT No.: PCT/EP2011/050436

§ 371 Date: Oct. 10, 2011

(30) Foreign Application Priority Data
Feb. 2, 2010 (DE) 10 2010 006 750.4
Jun. 2, 2010 (DE) 10 2010 029 653.8

(51) Int. Cl. B65G 13/02; C23C 16/00

(52) U.S. Cl. 118/729; 198/782

(57) ABSTRACT

Conveyor devices, in particular for use in substrate treatment devices, and configurations of substrate treatment devices, in particular horizontal coating installations for the mass coating of plate-like substrates during the production of solar cells are provided. The conveyor device comprises a multiplicity of conveyor rollers, each mounted rotatably at both ends thereof. During operation of the conveyor device, at least one conveyor roller is displaceable axially, i.e. parallel to the axis of rotation thereof.

The invention relates to conveyor devices, in particular for use in substrate treatment devices, and to configurations of substrate treatment devices, in particular horizontal coating installations for the coating of plate-like substrates.

In the case of known substrate conveyor devices in coating installations for plate-like substrates, e.g. glass plates, in which high substrate temperatures are required in order to achieve desired layer properties, use is preferably made of ceramic rollers, which form a conveyor plane on which the substrates are conveyed horizontally through the coating installation.

For float glass plates which are to be coated in the glass softening temperature range (float glass Tg about 540° C.) or at a higher temperature, it is necessary to provide each point of the plate with mechanical support over short intervals. Otherwise, the result may be undesirable, permanent deformations, which render further processing of the plates impossible. The intervals over which mechanical support has to be provided are in the region of a few seconds, depending on the temperature and glass properties. In practice, this is accomplished by the selection of a spacing between conveyor rollers, depending on the process conveying speed, temperature and glass properties, which ensures that the mechanical support mentioned above is provided.

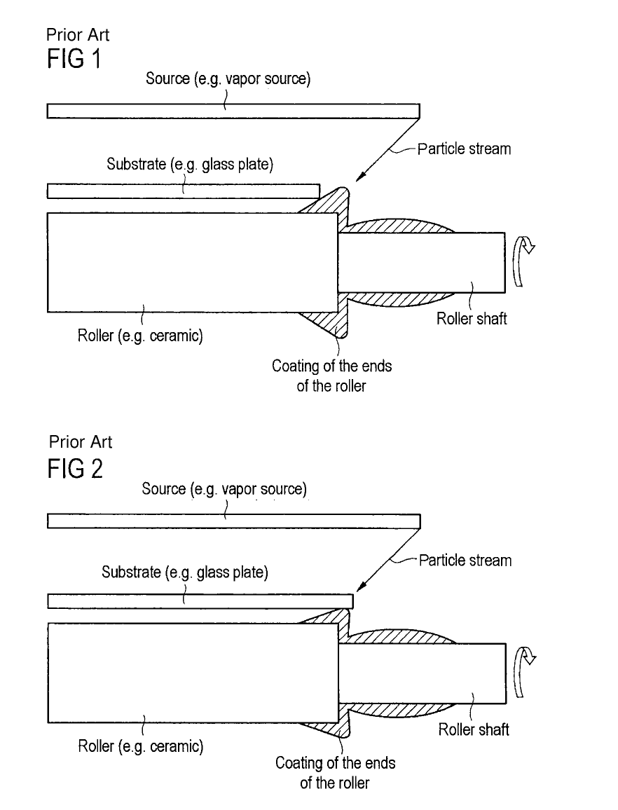

FIG. 1 shows a known conveyor device within the coating region of a substrate treatment installation. Substrates are conveyed horizontally through said installation under a vapor source on horizontally arranged conveyor rollers. In the example shown, the conveyor rollers have a central region with a relatively large diameter and an end region with a relatively small diameter.

Continuous operation of the coating device increasingly leads to undesirable coating of the ends of the conveyor rollers, even in the region in which the substrate bears on the conveyor rollers. As a result, the plates are no longer supported over their entire surface. Finally, the coating has the effect that the plates are no longer reliably conveyed, and so cleaning is required. In this respect, protective baffles between the vapor source and the conveyor rollers do not afford any advantage, since, in order to reduce undesirable coating, they have to be arranged very close to the substrate. Layers which have grown on the baffles may therefore make contact with the substrate. Screens fitted further away, although they might reduce the undesirable coating, also lead to an undesirable decrease in the layer thickness in the edge region of the substrates.

The cause of the coating of the ends of the conveyor rollers, which in practice results in thickening of the ends of the conveyor rollers (also referred to as “dog bone”), is that, depending on geometrical conditions (projection of and distance from the vapor source to the substrate), regions of the conveyor rollers which face toward the coating source are exposed to the vapor stream. In the illustration shown in FIG. 1, this relates primarily to the top regions of the conveyor roller surface which face toward the coating source, since the coating source is arranged above the conveyor device in relation to the cross section of the conveyor rollers. In addition, the coating process itself governs which regions of the ends of the conveyor rollers are coated.

Coating processes carried out with vapor sources at very low residual gas pressures therefore result in undesirable coating of the ends of the conveyor rollers in the manner explained, largely on the projection surface of the coating source.

If, however, process gases are admitted, the undesirable coating can occur on a much larger scale owing to the fact that the particles to be condensed collide with the process gas particles. The direction in which the particles to be condensed move changes considerably. Further regions of conveyor rollers are coated as a result. The coating on the rear side of the substrate in the edge region of the substrate (also known under the term “wrap around sputtering” in sputtering) is also the consequence of collisions of particles with the process gas particles as they move from the sources to the substrate.

FIG. 2 shows a conveyor device, similar to the illustration in FIG. 1, within the coating region of a substrate treatment installation, in which, however, the conveyor roller support is set back from the substrate edge, i.e. the substrate protrudes beyond the central regions of the conveyor roller on which the substrate bears and which have a larger diameter than the end regions. This arrangement is more advantageous than the one shown in FIG. 1, since the substrate shadows the central regions of the conveyor rollers, which serve for supporting the substrate, with respect to the vapor stream. If the substrate support is retracted far enough with respect to the substrate edge, the substrate support, which is important for the conveying operation, is not coated.

The coating of the conveyor rollers, which is uniform to the greatest possible extent owing to the periodic substrate gaps, leads to an increase in the effective diameter of the conveyor rollers which is decisive for the conveying operation, and in this context this can be regarded as much less critical. The increase in the effective diameter of the conveyor rollers can be minimized by observing the smallest possible substrate gaps. Furthermore, it is possible to counter the effect by selecting appropriately large diameters of the conveyor rollers. In addition, the rollers in question can be driven at a variable speed. In principle, it is thereby possible to keep the circumferential speed of the rollers constant by reducing the rotational speed with an increasing layer thickness.

In order to achieve maintenance-free production cycles which are as long as possible, it is necessary to minimize the layer thickness on the conveyor rollers, in particular in the region of the ends of the conveyor rollers in the region of the substrate edge. Slightly larger effective diameters of the conveyor rollers in the region of the substrate edges may by all means be tolerated, if these do not lead to conveying problems.

This object is achieved by a conveyor device having the features of Claim 1 and also by a substrate treatment installation having the features of Claim 10. The dependent claims describe configurations and developments.

The proposed conveyor device, which is suitable in particular for use in a substrate treatment device, comprises a multiplicity of horizontally arranged conveyor rollers, the uppermost surface lines of which form a bearing plane for substrates to be conveyed, wherein the conveyor rollers are each mounted rotatably in a rotary bearing at both their ends, and is characterized in that, during operation of the conveyor device, at least one conveyor roller is displaceable axially, i.e. parallel to the axis of rotation thereof.

For this purpose, it may be provided, for example, that the conveyor roller is arranged displaceably together with its rotary bearings. In this respect, by way of example, every second conveyor roller may be displaceable in one direction and the conveyor rollers lying therebetween in each case may be displaceable in the opposite direction. If a plurality of conveyor rollers are displaceable, this can be realized, for example, by combining the rotary bearings of all the conveyor rollers in two oppositely arranged banks of bearings and arranging said banks of bearings such that they are displaceable synchronously, as a result of which all the conveyor rollers are displaced axially.

In another configuration, it is provided, by contrast, that at least one end of the conveyor roller is mounted rotatably and axially displaceably in the rotary bearing. As a result, the rotary bearing itself does not have to be displaced, but instead the conveyor roller slides in the rotary bearing along its axis of rotation.

For this purpose, it may further be provided that the end of the conveyor roller is connected to an adjustment element such that actuation of the adjustment element brings about axial displacement of the conveyor roller. By way of example, such an adjustment element may comprise a toothed-rack drive, a lever mechanism or similar means familiar in the art.

In one configuration, it is proposed that the adjustment element is mounted pivotably, and pivoting of the adjustment element brings about axial displacement of the conveyor roller. Here, the adjustment element may comprise a pivotably mounted lever, which is connected to one or more conveyor rollers and, by way of example, is in the form of a plate which is oriented parallel to the conveying direction of the substrates and is mounted pivotably about an edge running parallel to the conveying direction. At its end which lies opposite the pivot axis, this plate can be connected to the ends of a plurality of conveyor rollers. Pivoting of the plate about the pivot axis thus has the effect that the conveyor rollers connected to it are displaced along the axes of rotation thereof, i.e. transversely to the conveying direction of the substrates. An electromotive drive, a hydraulic or pneumatic cylinder, a manually operated spindle drive or other means familiar in the art may be provided, by way of example, for actuating the adjustment element.

Furthermore, it may be provided that two adjustment elements are connected to at least in each case one end of a conveyor roller such that simultaneous actuation of the adjustment elements brings about axial displacements of the respective conveyor rollers in opposite directions. Here, the adjustment elements may be adjustable synchronously, for example in that they are connected to the same spindle drive which has a portion with a left-hand thread and a portion with a right-hand thread, and therefore actuation of the spindle drive brings about opposed pivoting movements of the two adjustment elements which cause the conveyor rollers connected in each case to the adjustment elements to be displaced in opposite directions. The two adjustment elements can be mounted pivotably about one and the same pivot axis.

In one development of the conveyor device proposed, it is provided that a baffle having a counter sputtering area arranged underneath the contact plane is arranged between two respective adjacent conveyor rollers and is axially displaceable together with at least one of the two adjacent conveyor rollers. The penetration of stray vapor into the space between the conveyor rollers is thereby prevented or at least greatly reduced. As a result, the undesirable coating on the rear side of the substrates is also prevented or at least greatly reduced.

According to one configuration, the baffle is configured as a packing element, which extends from the counter sputtering area into the space between the conveyor rollers. As a result, the volume of the chamber of a substrate treatment installation to be evacuated is reduced, and therefore the evacuation proceeds more quickly and with less energy consumption.

Furthermore, it may be provided that the conveyor rollers have a central region with a relatively large diameter and end regions with a relatively small diameter, and the end regions are covered at least partially by the baffles. This has the effect that the conveyor rollers themselves do not undergo any undesirable coating whatsoever. The substrates lie on the central regions which protrude through the counter sputtering plane formed by the baffles, and therefore the substrates can be conveyed horizontally thereon. In the region next to the substrates at the side, however, the end regions of the conveyor rollers are covered completely by the baffles owing to their relatively small diameter compared to the central regions, and therefore stray vapor cannot penetrate to said end regions.

According to a further configuration, it is provided that drive rollers are arranged immovably in the axial direction, but rotatably, on the rotary bearings, and the ends of the conveyor rollers are guided through said drive rollers such that a torque acting on the drive roller is transferred onto the conveyor roller, but an axial force acting on the conveyor roller is not transferred onto the drive roller. This has the effect that the drive rollers, which are usually driven by a common flexible drive means, for example a drive belt or a drive chain and a drive means operatively connected thereto, for example an electric motor, are arranged immovably and remain within the chamber of a substrate treatment device despite the displacement of the conveyor rollers, i.e. the entire drive device of drive rollers, flexible drive means and drive device is arranged at a fixed position within the chamber and remains uninfluenced by the displacement of the conveyor rollers.

In the text which follows, the invention is explained in more detail with reference to exemplary embodiments and associated drawings.

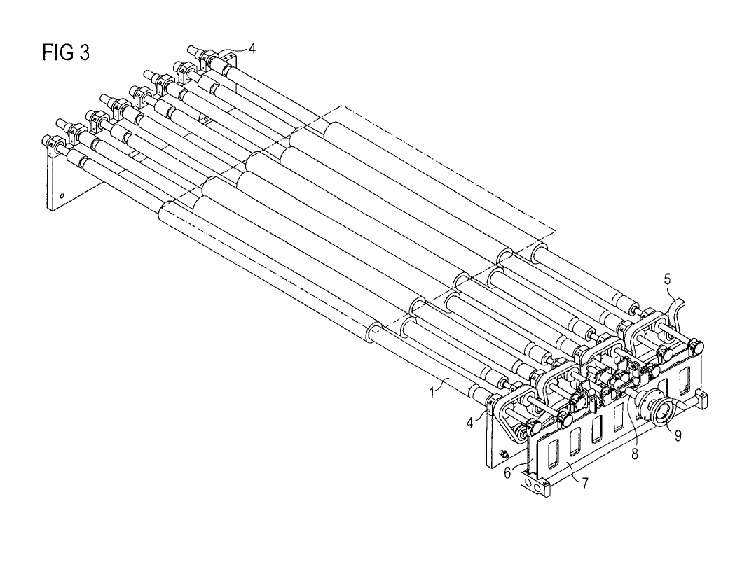

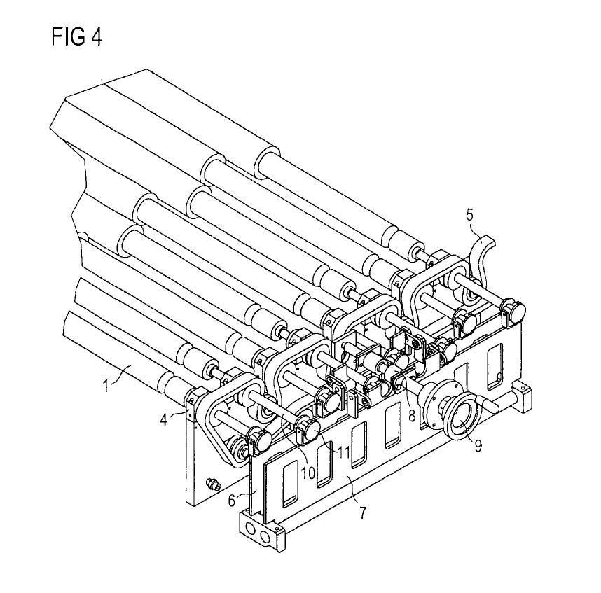

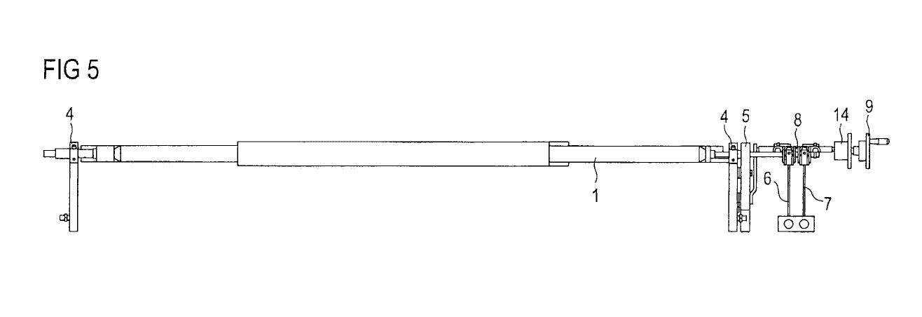

FIGS. 3 to 5 show a first exemplary embodiment, and

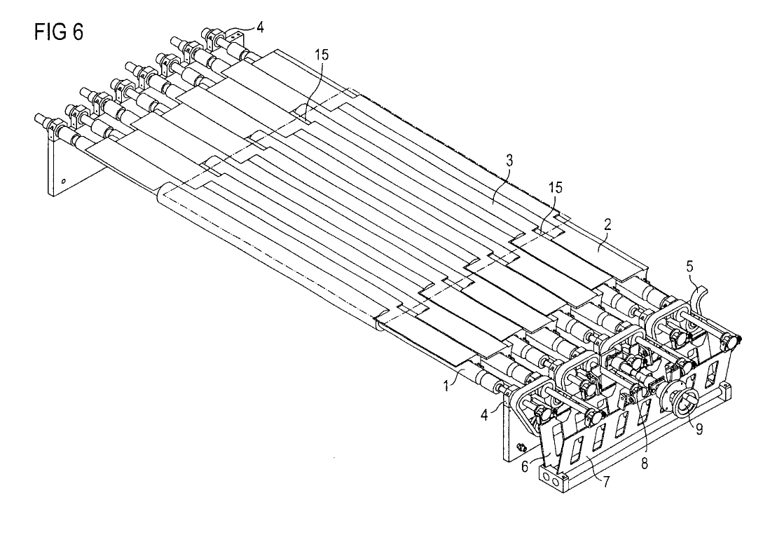

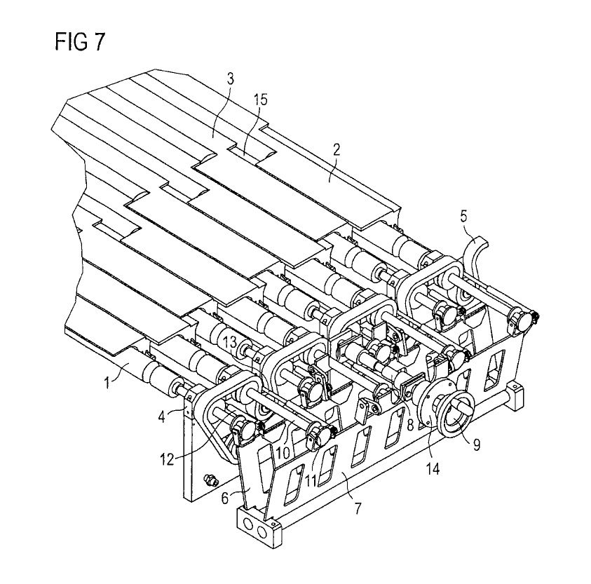

FIGS. 6 to 8 show a second exemplary embodiment of the proposed conveyor device.

In both exemplary embodiments, the conveyor rollers are formed axially, i.e. formed displaceably parallel to the axes of rotation thereof.

A first exemplary embodiment therefor is shown in various views in FIGS. 3 to 5.

The conveyor device shown comprises a multiplicity of horizontally arranged conveyor rollers, the uppermost surface lines of which form a bearing plane for substrates to be conveyed, wherein the conveyor rollers are each mounted rotatably in a rotary bearing at both their ends. During operation of the conveyor device, the conveyor rollers are displaceable axially, i.e. parallel to the axis of rotation thereof. This is realized in the manner described below.

The conveyor rollers are each mounted at both ends rotatably and axially displaceably in rotary bearings. The rotary bearings of all the conveyor rollers are arranged in two banks of bearings, which are arranged immovably opposite one another within the installation chamber (not shown). The banks of bearings extend parallel to the conveying direction of the substrates, i.e. transversely to the axes of rotation of the conveyor rollers.

The conveyor rollers each have a roller body, which is made of a ceramic material and has a central region with a relatively large diameter and end regions with a relatively small diameter. The ends of the conveyor rollers are formed by metal shafts, which are connected to the ceramic roller body via end caps. The free ends of the metal shafts are provided with a coupling element. The metal shafts are mounted rotatably and axially displaceably in a rotary bearing between the end cap and the coupling element.

On that side which faces toward the viewer, a drive roller in which the metal shaft is likewise axially displaceable is fitted to the rotary bearing. The drive rollers are connected to one another by a flexible drive means, as a result of which a drive force of the flexible drive means is converted into a drive torque transmitted onto the respective metal shaft by the drive rollers, such that the conveyor rollers are made to rotate.

On that side which faces toward the viewer, the ends of the conveyor rollers are connected to an adjustment element via the coupling element such that actuation of the adjustment element brings about axial displacement of the conveyor roller.

Two adjustment elements in the form of plates, which are mounted pivotably about in each case a pivot axis and are arranged parallel to the banks of bearings, are connected alternately to the end of every second conveyor roller such that simultaneous actuation of the adjustment elements brings about axial displacements of the respective conveyor rollers in opposite directions. For this purpose, a manually operated spindle drive with a spindle and a hand wheel arranged outside the substrate treatment installation is provided. For this purpose, the spindle is guided through the wall (not shown) of the installation chamber by means of a rotary leadthrough. The spindle is connected to both adjustment elements, and the result of actuation of the hand wheel in one direction of rotation is that the adjustment elements pivot apart, whereas the result of actuation of the hand wheel in the other direction of rotation is that the adjustment elements pivot toward one another.

A conveyor roller drive with drive rollers and a flexible drive means ensures that the conveyor rollers rotate so as to convey the substrates at a constant speed. A second drive ensures that the conveyor rollers are displaced transversely to the plate conveying direction. The conveyor rollers n, n+2, n+4, etc. are displaceable to one side transversely to the conveying direction, and the conveyor rollers n+1, n+3, n+5, etc. are displaceable in the opposite direction transversely to the conveying direction. The conveyor rollers are displaced transversely to the conveying direction continuously or else intermittently.

This means that the conveyor rollers in question are always drawn out from the substrate edge region. The layer thickness on the conveyor roller in the bearing region of the substrate edge can therefore be kept tolerably small.

The end of the conveyor roller (more precisely: the transition point between the conveyor roller and the conveyor roller shaft) on the other side is drawn under the substrate. The specific situation governs whether the transition point between the conveyor roller and the conveyor roller shaft is located in the region of the substrate edge at the start of the production cycle or should already be located under the substrate. If the undesirable coating is considerable, the transition point between the conveyor roller and the conveyor roller shaft should already be located under the substrate.

In principle, it is also possible to draw out all of the conveyor rollers to one side, if this does not impair the conveying operation. If, however, the glass temperature is in the region of the softening point, it is necessary to draw out the conveyor rollers alternately to both sides, in order to ensure the necessary mechanical support of the substrates.

A second exemplary embodiment of the conveyor device is shown in various views in FIGS. 6 to 8.

As already described above, a further problem of the coating device described may be that the substrates are coated in the region of the edges on the rear side (wrap around sputtering). This applies, in particular, to coating processes in which, owing to an increased residual gas pressure or process gas pressure, particle collisions occur between the material to be deposited on the substrate and the gas particles. This affects both the edges parallel to the conveying direction and the edges transverse to the conveying direction, affecting the edges transverse to the conveying direction not at all or very slightly only when the gaps between the individual substrates are virtually closed or are only very small so that the passage of vapor particles is impossible or greatly restricted. In the case of horizontal coating installations, it has been possible to counter the rear-side coating to date only using covering frames or by placing the substrate on planar carriers.

One possible way of considerably reducing the undesirable coating of the rear side of the substrate in the region of the edges to a tolerable extent is that of arranging a surface behind the substrate which is located at a very small distance from the rear side of the substrate. Owing to the small distance, scattered vapor particles can only penetrate into the gap and be deposited on the rear side of the substrate in a comparatively greatly restricted manner. For this purpose, packing elements or baffles which form a virtually closed plane together with the conveyor rollers have to be inserted between the conveyor rollers. The packing elements or baffles are arranged such that a narrow gap is formed between the rear side of the substrate and the plane formed by the packing elements or baffles. The individual planes between the conveyor rollers can slide transversely to the conveying direction in a manner similar to the conveyor rollers.

A baffle having a counter sputtering area arranged underneath the contact plane of the substrates with the conveyor rollers is arranged between two respective adjacent conveyor rollers and is axially displaceable together with a conveyor roller.

The baffles are not configured as simple metal sheets but rather as packing elements which extend from the counter sputtering area into the space between the conveyor rollers and thus largely fill this space, in order to reduce the volume to be evacuated.

As in the exemplary embodiment shown in FIGS. 3 to 5, the conveyor rollers have a central region with a relatively large diameter and end regions with a relatively small diameter, and the end regions are covered at least partially by the baffles, such that they are protected against undesirable coating. The baffles have actuating elements, which comprise metal rods and coupling elements, which are connected to in each case one adjustment element, such that in each case a conveyor roller and a packing element form a unit and are moved together when the adjustment element is actuated. As already described above, these units are alternately slowly drawn out continuously, if appropriately intermittently, during the production cycle. In this case, the packing elements or baffles are also coated on the other side of the unit in each case.

The speed with which the conveyor rollers are displaced is to be chosen, depending on the coating rate, such that that side of the packing elements of baffles drawn under the substrate does not make contact with the substrate owing to the grown layer. In order to limit the coating of the packing elements or baffles and conveyor rollers outside the substrate edge, additional protective baffles (not shown in the figures) may also be installed thereabove.

Axially adjustable conveyor rollers 1 and baffles/packing elements 2 and 3 are driven in axial friction bearings 4 via the pivot levers 6 and 7 and also axial actuating elements/tension-compression rods 10 for the conveyor rollers 1 and actuating elements 12 and 13 for the packing elements/baffles 2 and 3 and are thereby displaced parallel to their axes of rotation. Via the hand wheel 9 (optionally via an electric drive, e.g. a stepper motor, or another suitable actuator), the spindle 8, having a portion with a right-hand thread and a portion with a left-hand thread, makes uniform adjustment of the conveyor rollers 1 possible. In this case, in a manner alternating in the conveying direction, the conveyor rollers 1 and also the baffles/packing elements 2 and 3 are moved axially outward to the left or to the right transversely to the conveying direction. The movement cycle is governed substantially by the incidental process-induced contamination of the conveyor rollers 1 and of the baffles/packing elements 2 and 3, which move at the same time as the conveyor rollers 1. The gap produced in the process between the baffles/packing elements 2 and 3 is closed by covering plates 15 (spring strip steel or the like).

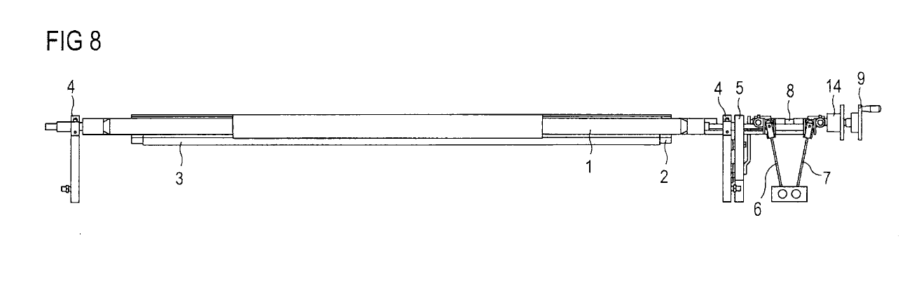

Reference symbol 14 in FIGS. 5 and 8 denotes the vacuum rotary leadthrough of the spindle 8 through a chamber wall (not shown) of a substrate treatment installation.

The drive element 5 (chain, toothed belt, metal strip or the like) is not moved axially; it remains in its original position.

### List of Reference Symbols

1 Conveyor roller
2 Packing element/baffle
3 Packing element/baffle
4 Axial friction bearing
5 Drive element/drive belt
6 Pivot lever
7 Pivot lever
8 Spindle
9 Hand wheel
10 Axial actuating element/tension-compression rod for conveyor roller
11 Coupling element
12 Actuating element for packing element/baffle
13 Actuating element for packing element/baffle
14 Rotary leadthrough for spindle
15 Cover element

1. Conveyor device, in particular for use in a substrate treatment device, comprising a multiplicity of horizontally arranged conveyor rollers, uppermost surface lines of said rollers forming a bearing plane for substrates to be conveyed, wherein the conveyor rollers are each mounted rotatably in a rotary bearing at both roller ends, and during operation of the conveyor device, at least one conveyor roller is displaceable axially, i.e. parallel to an axis of rotation of the at least one conveyor roller.

2. Conveyor device according to claim 1, wherein at least one end of the at least one conveyor roller is mounted rotatably and axially displaceably in a rotary bearing.

3. Conveyor device according to claim 2, wherein the at least one end of the at least one conveyor roller is connected to an adjustment element such that actuation of the adjustment element brings about axial displacement of the at least one conveyor roller.

4. Conveyor device according to claim 3, wherein the adjustment element is mounted pivotably, and pivoting of the adjustment element brings about axial displacement of the at least one conveyor roller.

5. Conveyor device according to claim 3, wherein two adjustment elements are connected to at least one end of respective conveyor rollers such that simultaneous actuation of the adjustment elements brings about axial displacements of the respective conveyor rollers in opposite directions.

6. Conveyor device according to claim 1, wherein a baffle having a counter sputtering area arranged underneath the bearing plane is arranged between two respective adjacent conveyor rollers and is axially displaceable together with at least one of the two adjacent conveyor rollers.

7. Conveyor device according to claim 6, wherein the baffle is configured as a packing element, which extends from the counter sputtering area into a space between the two adjacent conveyor rollers.

8. Conveyor device according to claim 6, wherein the conveyor rollers have a central region with a relatively large diameter and end regions with a relatively small diameter, and the end regions are covered at least partially by the baffles.

9. Conveyor device according to claim 1, wherein drive rollers are arranged immovably in the axial direction, but rotatably, on the rotary bearings, and the ends of the conveyor rollers are guided through said drive rollers such that a torque acting on a drive roller is transferred onto a conveyor roller, but an axial force acting on the conveyor roller is not transferred onto the drive roller.

10. Substrate treatment device, comprising an installation chamber with an entry lock and an exit lock and also, within the installation chamber, at least one substrate treatment device and a conveyor device for conveying plate-like substrates from the entry lock to the exit lock through the process chamber, wherein the conveyor device is designed according to claim 1.
